(19) United States
(12) Patent Application Publication
(10) Pub. No.: US 2014/0186618 A1
(43) Pub. Date: Jul. 3, 2014

(54) COATED ARTICLE AND METHOD FOR MAKING SAME

(71) Applicants: SHENZHEN FUTAIHONG PRECISION INDUSTRY CO., LTD., Shenzhen (CN); FIH (HONG KONG) LIMITED, Kowloon (HK)

(72) Inventors: XU LIU, Shenzhen (CN); DA-HUA CAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/863,923

(22) Filed: Apr. 16, 2013

(30) Foreign Application Priority Data
Dec. 27, 2012 (CN) 201210577644.8

(51) Int. Cl. C23C 14/35

(52) U.S. Cl. CPC C23C 14/352
USPC 428/336; 428/422; 204/192.15; 524/430; 524/437

(57) ABSTRACT

A coated article includes a substrate, a layer formed on the substrate. The layer containing polytetrafluroethylene and aluminum oxide, and the weight ratio of the aluminum oxide to the polytetrafluroethylene being between about 1:1.5 and 1:1.2. A method for making the coated article is also described.

### BACKGROUND

1. Technical Field

The present disclosure relates to coated articles and a method for making the coated articles.

2. Description of Related Art

Anodic oxidation, physical vapor deposition (PVD), and painting are the typical processes applied to decorate housings of electronic devices with color layers. However, when using these processes, the color layers often have poor contamination resistance property.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coated article.

FIG. 2 is a schematic view of a vacuum sputtering device for fabricating the coated article in FIG. 1.

### DETAILED DESCRIPTION

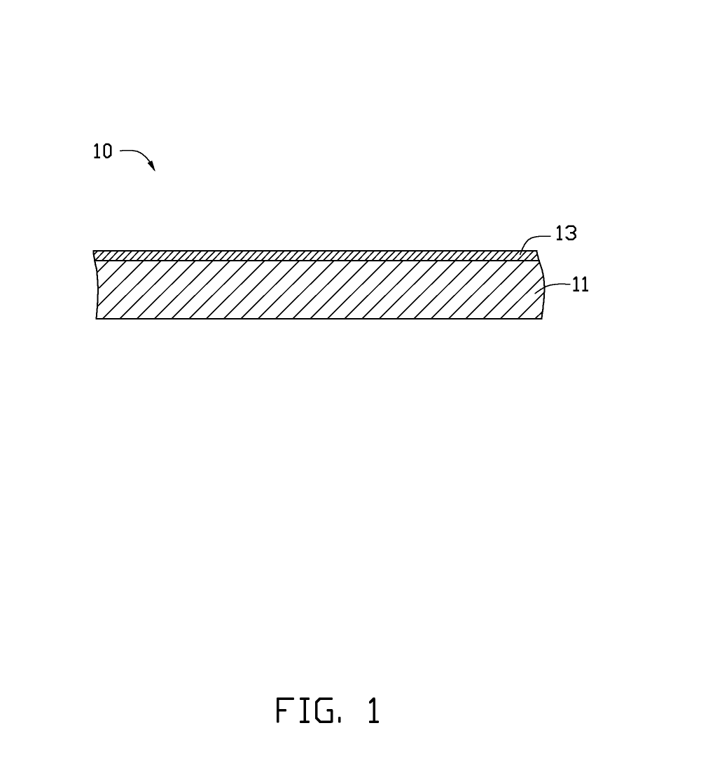

FIG. 1 shows a coated article 10 according to an exemplary embodiment. The coated article 10 includes a substrate 11 and a layer 13 formed on the substrate 11.

The substrate 11 is made of stainless steel, aluminum alloy, titanium alloy, or copper alloy.

In one embodiment, the layer 13 contains polytetrafluroethylene (PTFE) and aluminum oxide, and the mass ratio of the aluminum oxide to the PTFE is between about 1:1.5 and 1:1.2.

In another embodiment, the layer 13 contains PTFE and silicon-aluminum oxide, and the mass ratio of the silicon-aluminum oxide to the PTFE is between about 1:1.5 and 1:1.2. In the silicon-aluminum oxide, the ratio of the silicon atoms to the aluminum atoms is between about 1:1 and 3:7.

The thickness of the layer 13 is about 1 μm to about 2.2 μm. The layer 13 presents a white color. The layer 13 has a high hardness, a low friction coefficient, a good wear resistance, and a good contamination resistance.

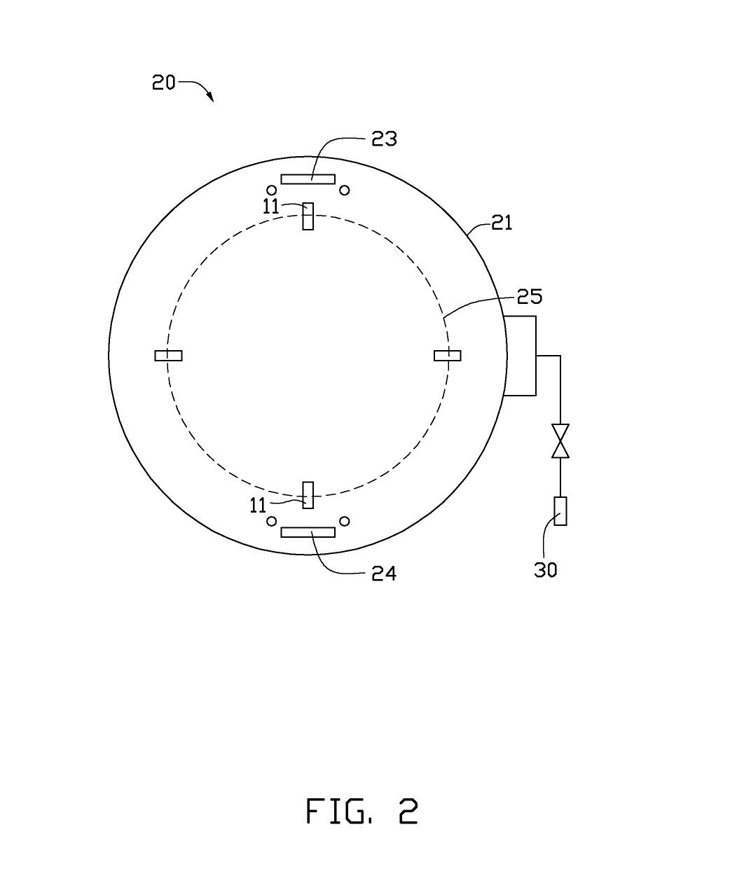

FIG. 2 shows a vacuum sputtering device 20, which includes a vacuum chamber 21 and a vacuum pump 30 connected to the vacuum chamber 21. The vacuum pump 30 is for evacuating the vacuum chamber 21. The vacuum chamber 21 has a first target 23, a second target 24, and a rotary rack (not shown) positioned therein. The rotary rack holds the substrate 11 to revolve along a circular path 25, and simultaneously, the substrate 11 rotates around its own axis. The first target 23 is made of aluminum or silicon-aluminum alloy. The second target 24 is made of PTFE. When the first target 23 is made of silicon-aluminum alloy, the ratio of the silicon atoms to the aluminum atoms is between about 1:1 and 3:7. Both the first target 23 and the second target 24 are applied radio frequency power.

A method for making the coated article 10 may include the following steps:

The substrate 11 is pretreated. The pre-treating process may include wiping the surface of the substrate 11 with alcohol and deionized water respectively, to remove impurities such as grease or dirt from the substrate 11. Then, the substrate 11 is dried.

The layer 13 may be vacuum sputtered on the substrate 11. Vacuum sputtering of the layer 13 is carried out in the vacuum chamber 21. The substrate 11 is positioned on the rotary rack. The vacuum chamber 21 is evacuated to about 1.0×10⁻³ Pa to about 1.0×10⁻² Pa and is heated to an inside temperature of about 160° C. to about 180° C. Argon gas (Ar) is used as the sputtering gas and is fed into the vacuum chamber 21 at a flow rate of about 150 standard-state cubic centimeter per minute (sccm) to about 200 sccm. Oxygen (O₂) is used as the reaction gas and is fed into the vacuum chamber 21 at a flow rate of about 120 sccm to about 150 sccm. The first target 23 is supplied with an electrical power of about 3 kw to about 8 kw, and the second target 24 is supplied with an electrical power of about 0.5 kw to about 1.0 kw. A negative bias voltage of about −100 V to about −200 V is applied to the substrate 11. Deposition of the layer 13 takes a total of about 60 min to about 120 min.

### EXAMPLE 1

The vacuum sputtering device 20 in example 1 was a radio frequency magnetron sputtering device.

The substrate 11 was made of stainless steel.

Sputtering to form the layer 13 on the substrate 11 took place, wherein the vacuum chamber 21 was heated to a temperature of about 160° C. Ar was fed into the vacuum chamber 21 at a flow rate of about 150 sccm. Oxygen was fed into the vacuum chamber 21 at a flow rate of about 120 sccm. The first target 23 was made of aluminum and was supplied with a power of about 3 kw. The second target 24 was supplied with a power of about 0.5 kw. A negative bias voltage of about −200 V was applied to the substrate 11. Deposition of the layer 13 took a total of about 120 min.

The thickness of the layer 13 was about 2.2 μm. The friction coefficient of the layer 13 was 0.09 tested by a friction coefficient tester (Labthink MXD-01). The Vickers-hardness of the layer 13 was HV450 tested by a Vickers-hardness tester. The oil contact angle of the layer 13 was tested by dropping bean oils on the layer 13 and testing the oil contact angle using a contact angle measuring instrument. The oil contact angle of the layer 13 was 152°, which demonstrated that the layer 13 had a good resistance to oil contamination.

### EXAMPLE 2

The vacuum sputtering device 20 in example 2 was the same in example 1.

The substrate 11 was made of titanium alloy.

Sputtering to form the layer 13 on the substrate 11 took place, wherein the vacuum chamber 21 was heated to a temperature of about 170° C. Ar was fed into the vacuum chamber 21 at a flow rate of about 180 sccm. Oxygen was fed into the vacuum chamber 21 at a flow rate of about 135 sccm. The first target 23 was made of aluminum and was supplied with a power of about 5 kw. The second target 24 was supplied with a power of about 0.8 kw. A negative bias voltage of about −120 V was applied to the substrate 11. Deposition of the layer 13 took a total of about 90 min.

The thickness, friction coefficient, Vickers-hardness, and oil contact angle of the layer 13 were tested by the same methods as in the example 1. The thickness of the layer 13 was about 1.7 μm. The friction coefficient of the layer 13 was 0.1. The Vickers-hardness of the layer 13 was HV420. The oil contact angle of the layer 13 was 150°, which demonstrated that the layer 13 had a good resistance to oil contamination.

### EXAMPLE 3

The vacuum sputtering device 20 in example 2 was the same in example 1.

The substrate 11 was made of stainless steel.

Sputtering to form the layer 13 on the substrate 11 took place, wherein the vacuum chamber 21 was heated to a temperature of about 180° C. Ar was fed into the vacuum chamber 21 at a flow rate of about 200 sccm. Oxygen was fed into the vacuum chamber 21 at a flow rate of about 150 sccm. The first target 23 was made of silicon-aluminum alloy and was supplied with a power of about 8 kw. The second target 24 was supplied with a power of about 1 kw. A negative bias voltage of about −100 V was applied to the substrate 11. Deposition of the layer 13 took a total of about 60 min.

The thickness, friction coefficient, Vickers-hardness, and oil contact angle of the layer 13 were tested by the same methods as in the example 1. The thickness of the layer 13 was about 1.0 μm. The friction coefficient of the layer 13 was 0.08. The Vickers-hardness of the layer 13 was HV400. The oil contact angle of the layer 13 was 156°, which demonstrated that the layer 13 had a good resistance to oil contamination.

According to the disclosure, the layer 13 has a white color, which makes the coated article have an aesthetically appealing appearance. The layer 13 has a high hardness, low friction coefficient, good wear resistance, and good stain resistance, which can improve the functional performance of the coated article 10.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a layer formed on the substrate, the layer comprising polytetrafluroethylene and aluminum oxide, the mass ratio of the aluminum oxide to the polytetrafluroethylene being between about 1:1.5 and 1:1.2.

2. The coated article as claimed in claim 1, wherein the layer has a thickness of about 1 μm to about 2.2 μm.

3. The coated article as claimed in claim 1, wherein the substrate is made of stainless steel, aluminum alloy, titanium alloy, or copper alloy.

4. The coated article as claimed in claim 1, wherein the layer has a white color.

5. A coated article, comprising:
a substrate; and
a layer formed on the substrate, the layer comprising polytetrafluroethylene and silicon-aluminum oxide, the mass ratio of the silicon-aluminum oxide to the polytetrafluroethylene being between about 1:1.5 and 1:1.2.

6. The coated article as claimed in claim 5, wherein the ratio of the silicon atoms to the aluminum atoms in the silicon-aluminum oxide is between about 1:1 and 3:7.

7. The coated article as claimed in claim 5, wherein the layer has a thickness of about 1 μm to about 2.2 μm.

8. The coated article as claimed in claim 5, wherein the substrate is made of stainless steel, aluminum alloy, titanium alloy, or copper alloy.

9. The coated article as claimed in claim 5, wherein the layer has a white color.

10. A method for making a coated article, comprising:
providing a substrate;
forming an layer on the substrate by magnetron sputtering method; the method using polytetrafluroethylene target, and target made of aluminum or silicon-aluminum alloy, argon as sputtering gas, and oxygen as reaction gas;
wherein the layer comprises polytetrafluroethylene and one chosen from aluminum oxide and silicon-aluminum oxide, and the mass ratio of one chosen from aluminum oxide and silicon-aluminum oxide to the polytetrafluroethylene is between about 1:1.5 and 1:1.2.

11. The method as claimed in claim 10, wherein magnetron sputtering the layer uses argon gas having a flow rate of about 150 sccm to about 200 sccm. oxygen having a flow rate of about 120 sccm to about 150 sccm, magnetron sputtering the layer is carried out at a temperature of about 160° C. to about 180° C.; the polytetrafluroethylene target is supplied with a power of about 3 kw to about 8 kw; and the target made of aluminum or silicon-aluminum alloy is supplied with a power of about 0.5 kw to about 1.0 kw; a negative bias voltage of about −100 V to about −200 V is applied to the substrate.

12. The method as claimed in claim 11, wherein vacuum sputtering the decorative layer takes about 60 min to about 120 min.

13. The method as claimed in claim 10, wherein for the target made of silicon-aluminum alloy, the ratio of the silicon atoms to the aluminum atoms is between about 1:1 and 3:7.

14. The method as claimed in claim 10, wherein the layer has a thickness of about 1 μm to about 2.2 μm.

15. The method as claimed in claim 10, wherein the substrate is made of stainless steel, aluminum alloy, titanium alloy or copper alloy.

16. The method as claimed in claim 10, wherein the layer has a white color.
